(19) United States
(12) Patent Application Publication
(10) Pub. No.: US 2006/0081996 A1
(43) Pub. Date: Apr. 20, 2006

(54) Semiconductor device having aluminum electrode and metallic electrode

(75) Inventors: Keiji Shinyama, Okazaki-city (JP); Ichiharu Kondo, Nagoya-city (JP); Kimiharu Kayukawa, Nisshin-city (JP); Shoji Miura, Nukata-gun (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/248,262

(22) Filed: Oct. 13, 2005

(30) Foreign Application Priority Data
Oct. 18, 2004 (JP) 2004-302915

(51) Int. Cl. H01L 23/48

(52) U.S. Cl. 257/773

(57) ABSTRACT

A semiconductor device includes: a semiconductor substrate; an aluminum electrode disposed on the surface of the substrate; a protection film disposed on the aluminum electrode and having an opening; and a metallic electrode disposed on a surface of the aluminum electrode through the opening of the protection film. The surface of the aluminum electrode includes a concavity. The concavity has an opening side and a bottom side, which is wider than the opening side. In the device, a concavity and a convexity of the metallic electrode become small.

### CROSS REFERENCE TO RELATED APPLICATION

This application is based on Japanese Patent Application No. 2004-302915 filed on Oct. 18, 2004, the disclosure of which is incorporated herein by reference.

### FIELD OF THE INVENTION

The present invention relates to a semiconductor device having an aluminum electrode and a metallic electrode.

### BACKGROUND OF THE INVENTION

A semiconductor device has a semiconductor substrate and an aluminum electrode formed on one side of the semiconductor substrate. This device is disclosed in, for example, Japanese Laid-Open Patent Publication No. 2002-110893, which corresponds to U.S. Pat. No. 6,693,350 etc, and Japanese Laid-Open Patent Publication No. 2003-110064, which corresponds to US Patent Publication No. 2003-0022464A1. A heat sink or the like is soldered to the aluminum electrode.

In this device, by using a bump electrode method disclosed in Japanese Laid-Open Patent Publication No. S63-305532, a protection film is formed on an aluminum electrode disposed on one side of a semiconductor substrate. Then, an opening is formed in the protection film. A metallic electrode for soldering or for bonding wire is formed on the surface of the aluminum electrode, which is exposed through the opening of the protection film.

The metallic electrode is made of an electroless Ni/Au plating film or a Ni/Au film deposited by a physical vapor deposition method (i.e., PVD method). The Ni/Au plating film is composed of a nickel-plating layer formed on the surface of the aluminum electrode and a gold-plating film on the nickel-plating film.

Here, when the metallic electrode is formed on the aluminum electrode by using a plating method or the like, an oxide film on the surface of the aluminum electrode is removed by a wet etching method before the metallic electrode is formed. Thus, deposition characteristics of the metallic electrode are improved.

In general, an interlayer insulation film is formed on one side of the semiconductor substrate. The aluminum electrode covers the insulation film. The aluminum electrode has a convexity and a concavity, which correspond to the shape of the patterned insulation film. Thus, the surface of the metallic electrode also has a concavity and a convexity. When a solder layer is formed on the metallic electrode, a solder diffusion layer is formed by heat in a soldering process. This solder diffusion layer is formed by mutually diffusing the metallic electrode and the solder layer.

The diffusion speed of the solder layer becomes larger, as the dimensions of a grain in the metallic electrode become larger. Therefore, it is preferred that the concavity and the convexity on the surface of the metallic electrode are small. When the thickness of the solder diffusion layer becomes large so that the solder diffusion layer reaches near the aluminum electrode, the solder layer may peel off from the aluminum electrode.

Further, when a bonding wire is bonded to the metallic electrode, bonding strength between the bonding wire and the metallic electrode becomes small. Further, when the concavity and the convexity of the metallic electrode are large, the distance between the metallic electrode and the interlayer insulation film becomes small. As a result, the metallic electrode may contact the interlayer insulation film, so that electrical fault such as Vt fault is occurred.

Specifically, when a metallic heat sink is soldered on the metallic electrode, endurance of bonding strength between the metallic heat sink and the metallic electrode becomes short. This is because tin in the solder layer 60 is rapidly diffused into the metallic electrode because of thermal history.

The above problems may occur not only the case where the metallic electrode is made of a plating film but also the case where the metallic electrode is made of a PVD film.

### SUMMARY OF THE INVENTION

In view of the above-described problem, it is an object of the present invention to provide a semiconductor device having an aluminum electrode and a metallic electrode.

A semiconductor device includes: a semiconductor substrate; an aluminum electrode disposed on the surface of the substrate; a protection film disposed on the aluminum electrode and having an opening; and a metallic electrode disposed on a surface of the aluminum electrode through the opening of the protection film. The surface of the aluminum electrode includes a concavity. The concavity has an opening side and a bottom side, which is wider than the opening side.

The metallic electrode formed on the aluminum electrode is prevented from penetrating into the concavity of the aluminum electrode, so that the concavity and the convexity of the metallic electrode become small. Thus, the bonding properties of the aluminum electrode are improved. Further, electric fault of the device is reduced.

Alternatively, the concavity may be provided in such a manner that the surface of the aluminum electrode is etched for stacking the metallic electrode on the etched surface of the aluminum electrode, and the metallic electrode is capable of soldering or wire bonding on a surface of the metallic electrode.

Alternatively, the bottom side of the concavity may be provided in such a manner that an inside of a grain of aluminum in the aluminum electrode is etched. Further, the opening side of the concavity may be provided in such a manner that a grain boundary of a grain of aluminum in the aluminum electrode is etched.

### BRIEF DESCRIPTION OF THE DRAWINGS

The above and other objects, features and advantages of the present invention will become more apparent from the following detailed description made with reference to the accompanying drawings. In the drawings:

FIG. 1 is a cross sectional view showing a semiconductor device according to a first embodiment of the present invention;

FIG. 2A is a partially enlarged cross sectional view showing an emitter electrode in the device according to the first embodiment, and FIG. 2B is a partially enlarged cross sectional view showing an interface between an aluminum electrode and a metallic electrode in the device shown in FIG. 2A;

FIGS. 3A to 3C are partially enlarged cross sectional views explaining a method for forming the emitter electrode and the gate electrode in the device according to the first embodiment;

FIG. 4 is a graph showing a relationship between a distance and a defect rate of soldering in the device according to the first embodiment;

FIG. 5 is a graph showing a relationship between the distance and a defect rate of Vt in the device according to the first embodiment;

FIG. 6 is a partially enlarged cross sectional view showing a stacking structure of an aluminum electrode and a metallic electrode in a semiconductor device according to a second embodiment of the present invention; and

FIGS. 7A to 7C are partially enlarged cross sectional views explaining a method for forming a metallic electrode as a comparison of the first embodiment.

### DETAILED DESCRIPTION OF THE PREFERRED EMBODIMENTS

### First Embodiment

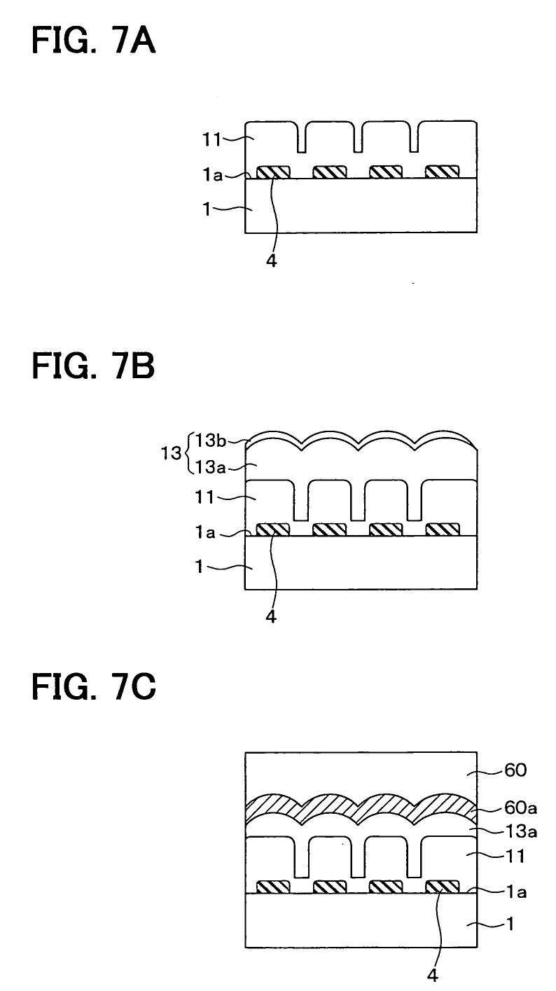

The inventors have preliminarily studied about bonding between a metallic electrode and a solder layer. An example method of forming a metallic electrode on an aluminum electrode by a Ni/Au plating method is shown in FIGS. 7A to 7C. An interlayer insulation film 4 is formed on one side of a semiconductor substrate 1. The insulation film 4 is patterned, and electrically insulates between a gate and an emitter. An aluminum electrode 11 is deposited on the one side of the substrate 1 to cover the insulation film 4 by using a sputtering method or a vapor deposition method.

As shown in FIG. 7A, the aluminum electrode 11 has a convexity and a concavity, which correspond to the shape of the insulation film 4. Then, an oxide film formed on the aluminum electrode 11 is removed by etching the surface of the aluminum electrode 11. As shown in FIG. 7B, a metallic electrode 13 is formed on the aluminum electrode 11. The metallic electrode 13 includes a nickel-plating layer 13a and a gold-plating layer 13b, which are stacked on the aluminum electrode 11 in this order.

In a case where the oxide film on the aluminum electrode 11 is removed, when the etching amount of the surface of the aluminum electrode becomes large, the concavity and the convexity on the surface of the aluminum electrode 11 becomes larger. Thus, a concavity and a convexity are formed on the surface of the metallic electrode 13.

As shown in FIG. 7C, when a solder layer 60 is formed on the metallic electrode 13 having large concavities and convexities, the thickness of a solder diffusion layer 60a becomes larger. The solder diffusion layer 60a is formed by heat in a soldering process. This solder diffusion layer 60a is formed by mutually diffusion between the metallic electrode 13 and the solder layer 60. When the metallic electrode 13 is made of a Ni/Au plating film, the solder diffusion layer 60a is made of mixture of nickel in the metallic electrode 13 and tin in the solder layer 60.

The diffusion speed of the solder layer 60 becomes larger, as the dimensions of a grain in the metallic electrode 13 becomes larger. Therefore, it is preferred that the concavity and the convexity on the surface of the metallic electrode 13 are small. When the thickness of the solder diffusion layer 60a becomes large so that the solder diffusion layer 60a reaches near the aluminum electrode 11, the solder layer 60 may be separated from the aluminum electrode 11.

Further, when a bonding wire is bonded to the metallic electrode 13 having a large concavity and convexity, bonding strength between the bonding wire and the metallic electrode 13 becomes small. Further, when the concavity and the convexity of the metallic electrode 13 are large, the distance between the metallic electrode 13 and the interlayer insulation film 4 becomes small. As a result, the metallic electrode 13 may contact the interlayer insulation film 4, so that electrical fault such as Vt fault is occurred.

Specifically, when a metallic heat sink is soldered on the metallic electrode 13, endurance of bonding strength between the metallic heat sink and the metallic electrode 13 becomes short. This is because tin in the solder layer 60 is rapidly diffused into the metallic electrode because of thermal history.

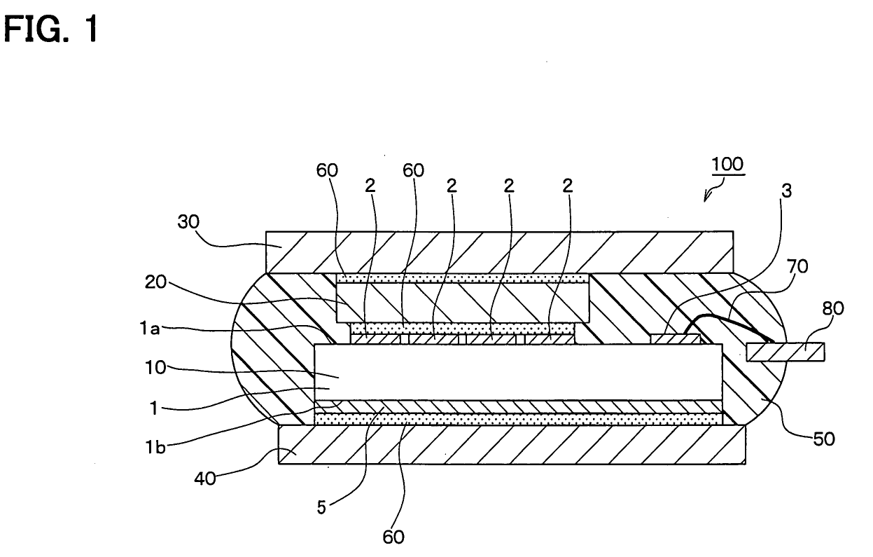

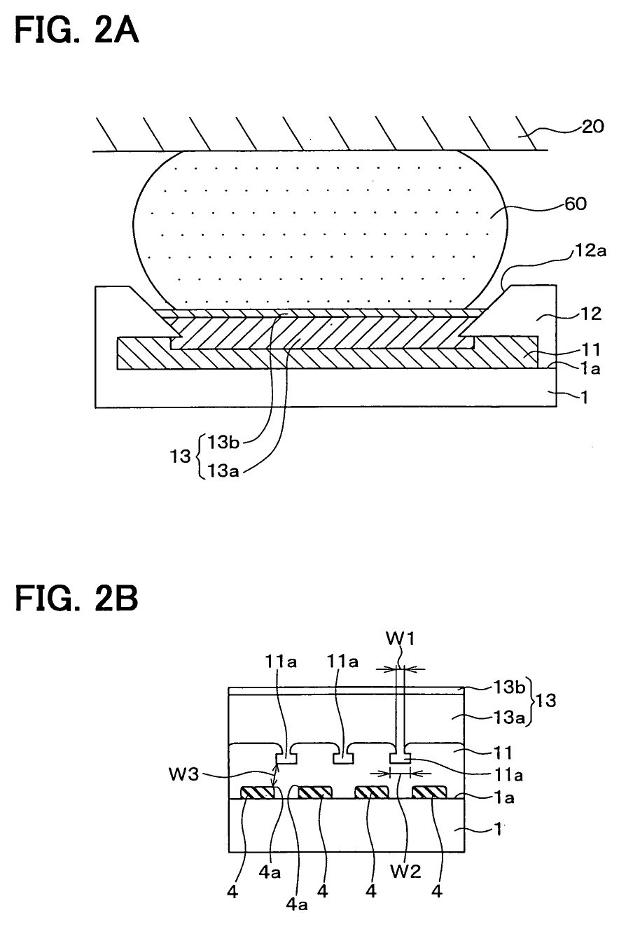

In view of the above points, a semiconductor device 100 according to a first embodiment of the present invention is manufactured, as shown in FIG. 1. FIG. 2A shows around an emitter electrode 2, and FIG. 2B shows an interface between an aluminum electrode 11 and a metallic electrode 13.

The device 100 includes a semiconductor chip 10, heat sinks 20, 30, 40 and a resin mold 50. The chip 10 includes an IGBT (i.e., insulated gate bipolar transistor). The chip 10 is sandwiched by the heat sinks 20, 30, 40 through a solder layer 60. The resin mold 60 seals the chip 10. This structure is defined as a both sides soldering mold structure.

The chip 10 includes a semiconductor substrate 1 such as a silicon substrate. The thickness of the substrate 1 is equal to or smaller than 250 μm. The chip 10, i.e., the substrate 1 includes a foreside surface 1a and a backside surface 1b. The foreside surface 1a is a device-forming surface, and the backside surface 1b is opposite to the foreside surface 1a. In FIG. 1, the foreside surface 1a is disposed on an upper side of the chip 10, and the backside surface 1b is disposed on a lower side of the chip 10.

An emitter electrode 2 and a gate electrode 3 are formed on the foreside surface 1a of the chip 10, and a collector electrode 5 is formed on the backside surface 1b of the chip 10. The first heat sink 20 is bonded to the emitter electrode 2 through the solder layer 60. The second heat sink 30 is bonded to the first heat sink 20 through the solder layer 60.

A bonding wire 70 is connected to the gate electrode 3 so that the gate electrode 3 is electrically connected to a lead 80 through the bonding wire 70. The lead 80 for connecting to an external circuit is disposed on a periphery of the chip 10.

The third heat sink 40 is bonded to the collector electrode 5 through the solder layer 60. The solder layer 60 is made of a Pb-free solder such as Sn—Ag—Cu solder and Sn—Ni—Cu solder.

The heat sink 20, 30, 40 are made of material having excellent heat conductivity such as copper. The bonding wire 70 is made of aluminum or gold. The bonding wire 70 is bonded to the gate electrode 3 by a conventional wire bonding method.

The detailed construction of the emitter electrode 2 is shown in FIGS. 2A and 2B. The detailed construction of the gate electrode 3 is almost the same as the emitter electrode 2. Although the emitter electrode 2 is bonded to the solder layer 60, the gate electrode 3 is bonded to the bonding wire 70.

As shown in FIG. 2A, the aluminum electrode 11 made of aluminum is formed on the foreside surface 1a of the substrate 1. The aluminum electrode 11 is an aluminum film formed by a PVD method such as a sputtering method and a vapor deposition method. The thickness of the aluminum electrode 11 is, for example, 1 μm. Specifically, the aluminum electrode 11 is made of pure aluminum, Al—Si or Al—Si—Cu.

An interlayer insulation film 4 is formed on the foreside surface 1a of the semiconductor substrate 1. The insulation film 4 is patterned, and electrically insulates between a gate and an emitter. The aluminum electrode 11 is disposed on the foreside surface 1a of the substrate 1 to cover the interlayer insulation film 4.

The surface of the aluminum electrode 11 is etched by a wet etching method so that an oxide film formed on the aluminum electrode 11 is removed. In this etching process, a concavity 11a is formed on the surface of the aluminum electrode 11, as shown in FIG. 2B.

The concavity 11a is formed between the insulation film 4, since a grain boundary is disposed between the insulation film 4. This is because the grain is easily formed and grown from a top of the insulation film 4 when the aluminum electrode 11 is deposited. Specifically, the grain is easily formed from a corner of the insulation film 4.

When the surface of the aluminum electrode 11 is etched, a part of the aluminum electrode 11, which has low film density, is easily etched, compared with a part having high film density. Therefore, after etching process, the concavity 11a is easily formed on the surface of the aluminum electrode 11 between the insulation film 4. The concavity 11a of the aluminum electrode 11 has a shape, a bottom side of which is wider than an opening side of the concavity 11a. Specifically, the opening side of the concavity has a dimension defined as W1, and the bottom side of the concavity 11a has another dimension defined as W2. The dimension W1 is smaller than the dimension W2.

The above shape of the concavity 11a is realized in such a manner that the inside of the grain of aluminum in the aluminum electrode 11 disposed on the bottom of the concavity 11a, the inside which is not the grain boundary of aluminum in the aluminum electrode 11, is etched so that the bottom of the concavity 11a is wider than the opening of the concavity 11a. Here, the opening of the concavity 11a is formed to etch the grain boundary of the grain of aluminum in the aluminum electrode 11.

The concavity 11a is observed by a cross sectional observation with a microscope. The opening side of the concavity 11a is etched along with the grain boundary extending in a thickness direction of the aluminum electrode 11. At a middle of the boundary, the aluminum electrode 11 is etched along with a lateral direction, i.e., a surface direction of the aluminum electrode 11 so that the inside of the grain instead of the grain boundary is etched. Thus, the bottom of the concavity 11a becomes wider.

Conventionally, the aluminum electrode is etched along with the grain boundary extending in the thickness direction of the aluminum electrode. Therefore, the concavity becomes deeper, so that the concavity and the convexity on the aluminum electrode become larger.

However, in this embodiment, the inside of the grain in the aluminum electrode 11 disposed on the bottom side of the concavity 11a is etched, the concavity 11a is comparatively shallow. Thus, the concavity and the convexity of the aluminum electrode 11 become smaller. This concavity 11a is formed by controlling etching conditions such as compositions of etchant and an etching temperature.

In FIG. 2B, the distance W3 between the bottom of the concavity 11a of the aluminum electrode 11 and the corner 4a of the insulation film 4 is equal to or larger than 0.5 μm. Preferably, the distance W3 is equal to or larger than 0.9 μm.

As shown in FIG. 2A, a protection film 12 made of electric insulation material is formed on the aluminum electrode 11. The protection film 12 is made of, for example, poly-imide resin. The protection film 12 is formed by a spin coating method.

An opening 12a is formed in the protection film 12 so that the surface of the aluminum electrode 11 is exposed from the protection film 12. The opening is formed by, for example, an etching process together with a photo-lithography method. The surface of the aluminum electrode 11 exposed through the opening 12a has the concavity 11a. The metallic electrode 13 is formed on the aluminum electrode 11. The metallic electrode 13 on the emitter electrode 2 works for soldering, and the metallic electrode on the gate electrode 3 works for wire bonding.

The metallic electrode 13 is formed by a plating method, and made of a Ni/Au stacked plating film, a Cu plating film, a Ni—Fe alloy plating film, or the like. In this embodiment, the metallic electrode 13 is made of an electroless Ni/Au plating film, which is composed of a Ni plating layer 13a and a gold plating layer 13b. The Ni plating layer 13a is formed on the surface of the aluminum electrode 11 by the electroless plating method, and the gold plating layer 13b is formed on the Ni plating layer 13a by the electroless plating method. Thus, the metallic electrode 13 is formed of a stacked film. The concavity and the convexity of the metallic electrode 13 become smaller, compared with the prior art.

The thickness of the nickel plating layer 13a is in a range between 3 μm and 7 μm. The thickness of the gold plating layer 13b is in a range between 0.04 μm and 0.2 μm. In this embodiment, the thickness of the nickel plating layer 13a is 5 μm, and the thickness of the gold plating layer 13b is 0.1 m.

The metallic electrode 13 is bonded to the metallic first heat sink 20 with the solder layer 60 made of Pb free solder. Thus, the aluminum electrode 11 is bonded to the metallic electrode 13 through the solder layer 60. The emitter electrode 2 and the gate electrode 3 in the chip 10 are made of a stacked film of the aluminum electrode 11 and the metallic electrode 13. The method for forming the emitter electrode 2 and the gate electrode 3 is described as follows.

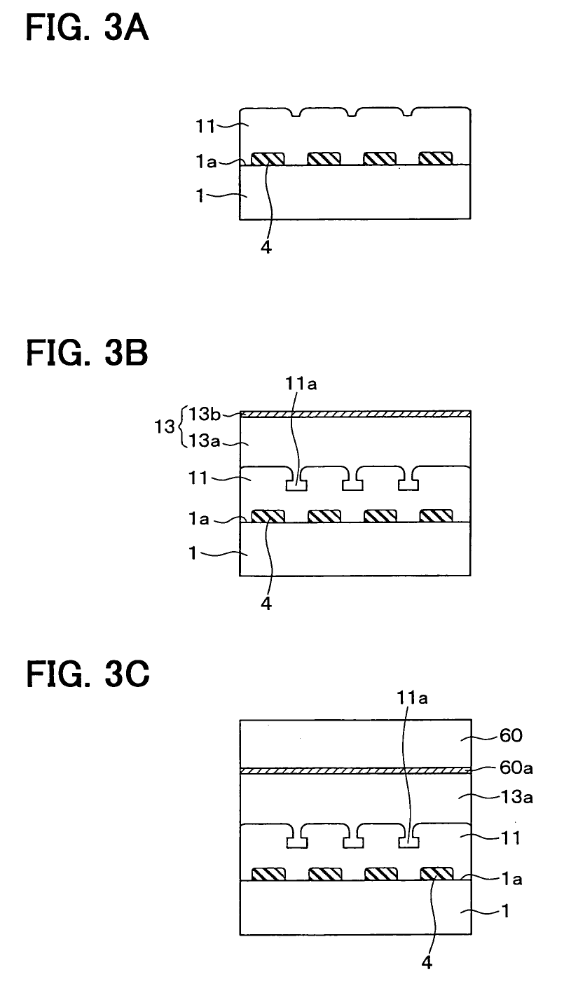

Firstly, as shown in FIG. 3A, the aluminum electrode 11 is formed on the foreside surface 12a of the substrate 1 by the PVD method such as the sputtering method and the vapor deposition method. Here, the surface of the aluminum electrode 11 can be formed smoothly. By controlling deposition conditions, the surface of the aluminum electrode 11 is formed smoothly. Thus, the concavity and the convexity of the surface of the aluminum electrode 11 become smaller after etching the surface of the aluminum electrode 11. Accordingly, the concavity and the convexity of the metallic electrode 13 disposed on the aluminum electrode 11 become smaller.

Then, the protection film 12 is formed on the aluminum electrode 11 by the spin coating method or the like. The opening 12a is formed in the protection film 12 by the photo-etching method or the like. The surface of the aluminum electrode 11 exposed through the opening 12a of the protection film 12 is etched by the wet etching method with using etchant of aluminum. In this etching process, an oxide film on the surface of the aluminum electrode 11 is removed. Thus, the concavity 11a is formed, and the surface of the aluminum electrode is cleaned.

Next, as shown in FIG. 3B, the metallic electrode 13 is formed on the surface of the aluminum electrode 11 having the concavity 11a. The metallic electrode 13 is formed of the electroless Ni/Au plating film by the electroless plating method. Thus, the emitter electrode 2 and the gate electrode 3, each of which is composed of the aluminum electrode 11 and the metallic electrode 3, are formed.

Next, as shown in FIG. 3C, the metallic electrode 13 is bonded to the first heat sink 20 through the solder layer 60. After soldering, the solder diffusion layer 60a is formed between the solder layer 60 and the metallic electrode 13. The gold plating layer 13b is substantially disappeared. The solder diffusion layer 60a is made of a Ni—Sn diffusion layer, which is formed of tin and nickel.

Here, the collector electrode 4 is formed on almost whole of the backside surface 1b of the substrate 1 by the sputtering method or the like. The collector electrode 4 is bonded to the third heat sink 40 with the solder layer 60. The collector electrode 4 is made of, for example, a Ti/Ni/Au film. Specifically, a Ti layer, a Ni layer and a Au layer are formed in this order on the backside surface 1b of the substrate 1 by the sputtering method or the like.

The resin mold 50 molds between the second heat sink 30 and the third heat sink 40 so that components disposed between the second and the third heat sinks 30, 40 are sealed with the resin mold 50. The lead 80 is sealed with the resin mold 50. Specifically, the connection portion between the lead 80 and the bonding wire 70 is sealed with the resin mold 50. The resin mold 50 is made of, for example, conventional molding resin such as epoxy resin, which is suitably used for electronic equipment. The resin mold 50 is formed by a transfer molding method or the like with using a mold.

Thus, the device 100 is completed. In the device 100, the heat generated in the chip 10 is transmitted to the heat sinks 20, 30, 40 through the solder layer 60 having excellent heat conductivity so that the heat is radiated outside of the device 100. Thus, the heat is radiated from both sides 1a, 1b of the chip 10. Further, each heat sink 20, 30, 40 works as an electric path connecting to the chip 10. Specifically, the emitter electrode 2 of the chip 10 is electrically connected to the external circuit through the first and the second heat sinks 20, 30. The collector electrode 4 of the chip 10 is electrically connected to the external circuit through the third heat sink 40.

Next, an assembling method of the device 100 is described as follows. The chip 10 having the electrodes 2, 3, 4 is prepared. Then, solder material is mounted on each electrode 2-4. The first and the third heat sinks 20, 40 are boned to the chip 10 through the solder layer 60. The gate electrode 3 and the lead 80 are electrically connected through the bonding wire 70 by the wire bonding method. Then, the second heat sink 30 is bonded to the outside of the first heat sink 20 through the solder layer 60. Then, the resin mold 50 is formed so that the device 100 is completed.

In the device 100, the concavity 11a formed on the surface of the aluminum electrode 11 has the opening side narrower than the bottom side of the concavity 11a. Accordingly, the metallic electrode 13 does not easily penetrate into the concavity 11a so that the concavity and the convexity of the metallic electrode 13 become small. Thus, the bonding strength of the aluminum electrode 11 is improved. Further, electric connection of the aluminum electrode 11 is improved.

Since the concavity and the convexity of the metallic electrode 13 are small, the solder diffusion layer 60a is limited from growing in a case where the solder layer 60 is formed on the metallic electrode 13. Thus, the bonding properties of the aluminum electrode 11 are improved. Here, since the grain boundary in the metallic electrode 13 is small, the diffusion rate is small; and therefore, the solder diffusion layer 60a becomes thin. Thus, the bonding properties between the emitter electrode 2 and the solder layer 60 are improved. Further, the bonding properties between the gate electrode 3 and the bonding wire 70 are improved, since the concavity and the convexity of the metallic electrode 13 are small.

The shape of the concavity 11a of the aluminum 11 is formed such that the inside of the grain of aluminum in the aluminum electrode, which is not the grain boundary and disposed on the bottom side of the concavity 11a, is etched. Thus, the bottom side of the concavity 11a becomes wider than the opening side of the concavity 11a. Further, the concavity 11a becomes shallower, i.e., the depth of the concavity 11a becomes smaller. Thus, the etching amount of the aluminum electrode 11 can be minimized, so that the concavity and the convexity of the aluminum electrode become small. Furthermore, when the concavity 11a is shallow, the distance W3 between the bottom of the concavity 11a, which corresponds to the bottom of the metallic electrode 13a, and the insulation film 4 becomes large. Thus, electric fault such as Vt fault is prevented from occurring. Here, the opening portion of the concavity 11a is formed such that the grain boundary of aluminum in the aluminum electrode 11 is etched.

The distance W3 between the bottom of the concavity 11a and the insulation film 4 is preferably equal to or larger than 0.5 μm. More preferably, the distance W3 is equal to or larger than 0.9 μm. This reason is described as follows.

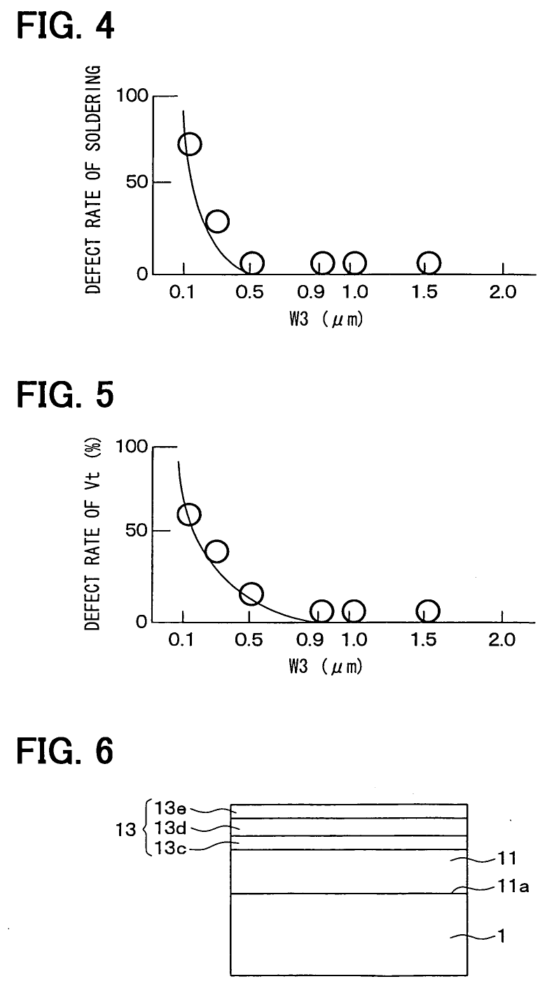

FIG. 4 shows a relationship between the distance W3 and defect rate of soldering. FIG. 5 shows a relationship between the distance W3 and defect rate of Vt. Here, the defect rate of soldering represents percentage of the device 100, the aluminum electrode 11 of which is separated from the solder layer 60 by the heat of soldering when the aluminum electrode 11 is soldered with the solder layer 60. The defect rate of Vt represents percentage of the device 100 having anomaly of Vt characteristics.

When the distance W3 is equal to or larger than 0.5 μm, the defect rate of soldering becomes much small. Thus, in this case, the bonding fault caused by the solder diffusion layer 60a is limited when the aluminum electrode 11 is soldered. When the distance W3 is equal to or larger than 0.9 μm, the defect rate of Vt becomes much small.

The solder layer 60 is made of Pb-free solder. The Pb-free solder does not include Pb. Therefore, using the Pb-free solder contributes to the environmental protection. However, since the Pb-free solder is harder than a conventional Pb solder, the stress applied to the metallic electrode 13 becomes large. Further, since amount of tin in the Pb-free solder is large, the solder diffusion layer 60a is easily formed when the aluminum electrode 11 is soldered. Therefore, when the solder layer 60 is made of Pb-free solder, in a conventional semiconductor device, an aluminum electrode is easily separated from a metallic electrode. On the other hand, in this device 100 according to the first embodiment, the bonding strength between the aluminum electrode 11 and the metallic electrode 13 is improved so that the aluminum electrode 11 is not separated from the metallic electrode 13.

The metallic electrode 13 is bonded to the first heat sink 20 through the solder layer 60. The bonding strength between the first heat sink 20 and the metallic electrode 13 is also improved.

Further, the thickness of the substrate 1 is equal to or smaller than 250 μm. When the thickness of the substrate 1 is large, the thermal stress becomes larger in a case where the aluminum electrode 11 is soldered. To control diffusion of the solder layer 60, the thickness of the substrate 1 is set to be equal to or smaller than 250 μm.

Although the device 100 has the both sides soldering mold structure, the device 100 can be another type of device as long as the device includes the semiconductor substrate 1, the aluminum electrode 11 disposed on the substrate 1, the protection film 12 disposed on the aluminum electrode 11 and having the opening 12a, and the metallic electrode 13 disposed on the surface of the aluminum electrode exposed through the opening 12a.

### Second Embodiment

A semiconductor device according to a second embodiment of the present invention is shown in FIG. 6. Specifically, FIG. 6 shows a stacking structure of the aluminum electrode 11 and the metallic electrode 13. The metallic electrode 13 is formed by the PVD method such as the sputtering method and the vapor deposition method. The thickness of the metallic electrode 13 is composed of, for example, a titan layer 13c having the thickness of 0.2 μm, a nickel layer 13d having the thickness of 0.5 μm and a gold layer 13e having the thickness of 0.1 μm.

The second embodiment also has the same advantages as the first embodiment. Specifically, the concavity and the convexity of the metallic electrode 13 disposed on the aluminum electrode 11 become smaller so that the bonding strength of the aluminum electrode 11 is improved. Further, electric fault of the device is reduced.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. A semiconductor device comprising:
a semiconductor substrate;
an aluminum electrode disposed on the surface of the substrate;
a protection film disposed on the aluminum electrode and having an opening; and
a metallic electrode disposed on a surface of the aluminum electrode through the opening of the protection film, wherein
the surface of the aluminum electrode includes a concavity, and
the concavity has an opening side and a bottom side, which is wider than the opening side.

2. The device according to claim 1, wherein
the concavity is provided in such a manner that the surface of the aluminum electrode is etched for stacking the metallic electrode on the etched surface of the aluminum electrode, and
the metallic electrode is capable of soldering or wire bonding on a surface of the metallic electrode.

3. The device according to claim 2, wherein
the bottom side of the concavity is provided in such a manner that an inside of a grain of aluminum in the aluminum electrode is etched.

4. The device according to claim 2, wherein
the opening side of the concavity is provided in such a manner that a grain boundary of a grain of aluminum in the aluminum electrode is etched.

5. The device according to claim 1, further comprising:
an interlayer insulation film disposed on the surface of the substrate, wherein
the interlayer insulation film has a predetermined pattern,
the aluminum electrode covers the interlayer insulation film,
a distance between a bottom of the concavity of the aluminum electrode and the interlayer insulation film is equal to or larger than 0.5 μm.

6. The device according to claim 5, wherein
the distance between the bottom of the concavity and the interlayer insulation film is equal to or larger than 0.9 μm.

7. The device according to claim 1, wherein
the aluminum electrode is made of one material selected from the group consisting of pure aluminum, Al—Si and Al—Si—Cu.

8. The device according to claim 1, wherein
the metallic electrode includes a nickel plating layer and a gold plating layer, which are stacked on the surface of the aluminum electrode in this order.

9. The device according to claim 8, wherein
the nickel plating layer and the gold plating layer are provided by an electroless plating method.

10. The device according to claim 1, wherein
the metallic electrode is provided by a physical vapor deposition method.

11. The device according to claim 1, wherein
the metallic electrode is capable of soldering with using a Pb-free solder.

12. The device according to claim 1, wherein
the metallic electrode is connected to a metallic heat sink through a solder layer.

13. The device according to claim 1, wherein
the substrate has a thickness equal to or smaller than 250 μm.
